(19) United States
(12) Patent Application Publication
(10) Pub. No.: US 2016/0071874 A1
(43) Pub. Date: Mar. 10, 2016

(54) INTEGRATED CIRCUIT DEVICE AND METHOD FOR MANUFACTURING THE SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/645,903

(22) Filed: Mar. 12, 2015

Related U.S. Application Data
(60) Provisional application No. 62/048,539, filed on Sep. 10, 2014.

(51) Int. Cl. H01L 27/115; H01L 21/28

(52) U.S. Cl. CPC H01L 27/11582; H01L 27/11556; H01L 21/28282; H01L 21/28273

(57) ABSTRACT

According to one embodiment, an integrated circuit device includes a substrate. The integrated circuit device also includes a stacked body provided on the substrate, insulating films and electrode films being alternately stacked in the stacked body. The integrated circuit device also includes a stopper member selectively provided in the electrode film in a bottom layer and a first stopper protection film provided on a side surface of the stopper member. The integrated circuit device also includes an insulating member provided immediately on the stopper member and configured to pierce through the stacked body in a stacking direction of the insulating films and the electrode films, a lower end of the insulating member disposed in the stopper member. The integrated circuit device also includes a semiconductor pillar provided in a side direction of the insulating member and configured to pierce through the stacked body in the stacking direction.

### CROSS-REFERENCE TO RELATED APPLICATIONS

This application is based upon and claims the benefit of priority from U.S. Provisional Patent Application 62/048,539, filed on Sep. 10, 2014; the entire contents of which are incorporated herein by reference.

### FIELD

Embodiments described herein relate generally to an integrated circuit device and a method for manufacturing the same.

### BACKGROUND

High integration of an integrated circuit device has been ongoing. However, a method for increasing an integration degree through improvement of lithography and etching techniques is approaching the limit. A stacked integrated circuit device has been proposed. In the stacked integrated circuit device, a stacked body in which word lines and interlayer insulating films are alternately stacked and silicon pillars piercing through the stacked body are provided. In the stacked body, slits for separating the word lines are formed and extend to a lower selection gate electrode. Stopper members for preventing the slits from piercing through the lower selection gate electrode are provided at the lower ends of the slits.

### BRIEF DESCRIPTION OF THE DRAWINGS

FIG. 1 is a sectional view illustrating an integrated circuit device according to a first embodiment;

FIGS. 2 to 17 are sectional views illustrating the method for manufacturing the integrated circuit device according to the first embodiment;

FIG. 18 is a graph illustrating diffusion length of tantalum in 60 seconds with heating temperature plotted on the abscissa and diffusion length plotted on the ordinate;

FIG. 19 is a graph illustrating diffusion length of tantalum in 60 minutes with heating temperature plotted on the abscissa and diffusion length plotted on the ordinate;

FIG. 20 is a sectional view illustrating an integrated circuit device according to a second embodiment;

FIGS. 21 to 24 are sectional views showing a method for manufacturing the integrated circuit device according to the second embodiment;

FIG. 25 is a sectional view illustrating the method for manufacturing the integrated circuit device according to a third embodiment; and

FIG. 26 is a sectional view illustrating a method for manufacturing an integrated circuit device according to a forth embodiment.

### DETAILED DESCRIPTION

According to one embodiment, an integrated circuit device includes a substrate. The integrated circuit device also includes a stacked body provided on the substrate, insulating films and electrode films being alternately stacked in the stacked body. The integrated circuit device also includes a stopper member selectively provided in the electrode film in a bottom layer and a first stopper protection film provided on a side surface of the stopper member. The integrated circuit device also includes an insulating member provided immediately on the stopper member and configured to pierce through the stacked body in a stacking direction of the insulating films and the electrode films, a lower end of the insulating member disposed in the stopper member. The integrated circuit device also includes a semiconductor pillar provided in a side direction of the insulating member and configured to pierce through the stacked body in the stacking direction.

According to one embodiment, a method for manufacturing an integrated circuit device includes depositing a first material on a first electrode film, selectively removing the first member to form a stopper member and forming a first stopper protection film on a side surface of the stopper member. The method for manufacturing an integrated circuit device also includes depositing a third material on the first electrode film other than a portion where the stopper member and the first stopper protection film are formed and forming a filling film. The method for manufacturing an integrated circuit device also includes alternately stacking second insulating films and second electrode films on the stopper member, the first stopper protection film, and the filling film to form a stacked body. The method for manufacturing an integrated circuit device also includes forming, immediately on the stopper member, a slit that pierces through the stacked body in a stacking direction of the second insulating films and the second electrode films and reaches inside the stopper member. The method for manufacturing an integrated circuit device also includes filling the slit with an insulating material to form an insulating member. The method for manufacturing an integrated circuit device also includes forming, in a side direction of the slit, a memory hole that pierces through the stacked body in the stacking direction. The method for manufacturing an integrated circuit device also includes forming a memory film on a side surface of the memory hole and filling a semiconductor material in the memory hole to form a semiconductor pillar.

Embodiments of the invention are described below with reference to the drawings.

### First Embodiment

First, a first embodiment is described.

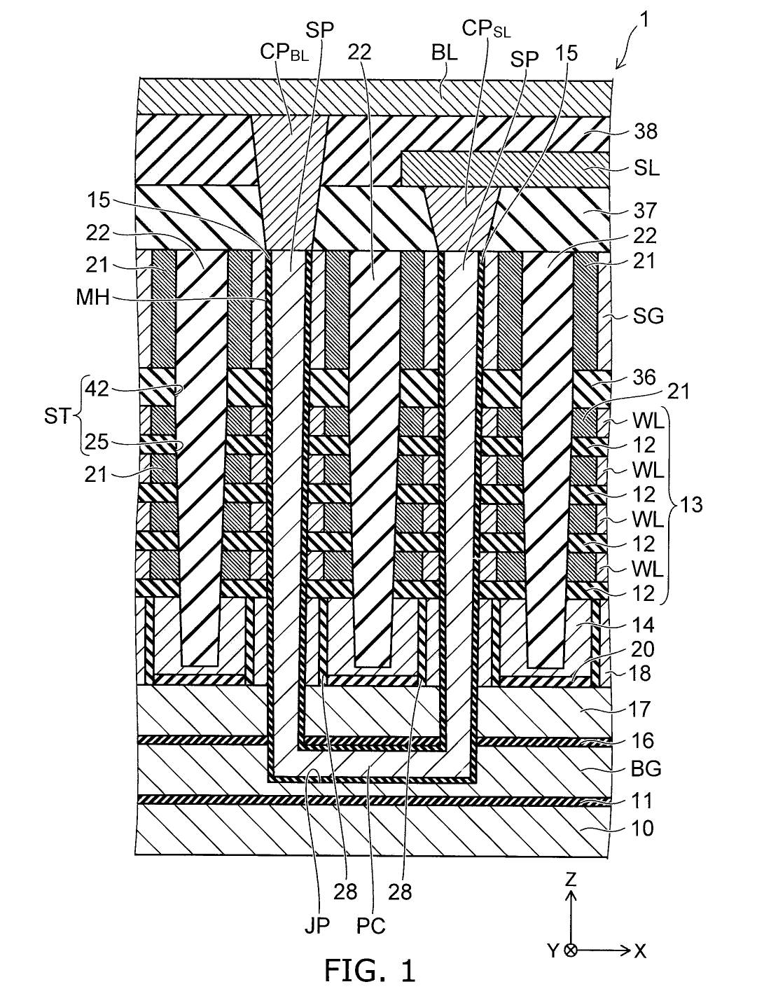

FIG. 1 is a sectional view illustrating an integrated circuit device according to the embodiment.

The integrated circuit device according to the embodiment is a stacked integrated circuit device.

As shown in FIG. 1, in an integrated circuit device 1 according to the embodiment, a silicon substrate 10 is provided in the bottom layer. An insulating film 11 is provided on the silicon substrate 10.

In the following description, in the specification, an XYZ rectangular coordinate system is adopted for convenience of description. That is, in FIG. 1, two directions parallel to a contact surface of the silicon substrate 10 and the insulating film 11 and orthogonal to each other are represented as an “X-direction” and a “Y-direction. An upward direction perpendicular to the contact surface of the silicon substrate 10 and the insulating film 11 is represented as a “Z-direction”.

On the insulating film 11 of the integrated circuit device 1, a back gate electrode BG, an interlayer insulating film 16, an electrode film 17, a filling film 18, a stopper member 14, a stacked body 13, an interlayer insulating film 36, a selection gate electrode SG, an interlayer insulating film 37, a source line SL, an interlayer insulating film 38, and a bit line BL are provided from the bottom along the Z-direction. In the stacked body 13, insulating films 12 and word lines WL are alternately repeatedly stacked.

The stopper member 14 is present at the distal ends of slits ST and extends in the Y-direction. When the slits ST are formed, the stopper member 14 is used to prevent the slits ST from piercing through the stacked body 13. The stopper member 14 is formed of a metal material such as tantalum (Ta), tantalum titanium (TaTi), hafnium (Hf), or tungsten (W) and oxide or nitride of the metal material.

A barrier metal film 20 is provided in a lower part of the stopper member 14. Stopper protection films 28 for preventing the material of the stopper member 14 from dispersing into the filling film 18 are provided on a side surface of the stopper member 14. The stopper protection films 28 are formed of, for example, silicon oxide (SiO) or silicon nitride (SiN).

On the stopper member 14, lower sections 25 of the slits ST for separating the word lines WL are provided to pierce through the stacked body 13 in the Z-direction. On the lower sections 25 of the slits ST, upper sections 42 of the slits ST are formed to pierce through the stacked body in the Z-direction from the interlayer insulting film 37 to the interlayer insulating film 36. Insulating members 22 made of an insulating material are provided in the lower sections 25 of the slits ST and the upper sections 42 of the slits ST. The insulating members 22 extend in the Y-direction.

Silicide 21 is formed in portions intruding into the word lines WL side from surfaces where the word lines WL and the insulating members 22 are in contact and portions intruding into the selection gate electrode SG side from surfaces where the selection gate electrode SG and the insulating members 22 are in contact.

On the insulating film 11, on side directions of the insulating members 22, memory holes MH are formed to pierce through the stacked body in the Z-direction from the interlayer insulating film 37 to an upper layer portion of the back gate electrode BG. The lower ends of a pair of memory holes MH are connected to a joining section JP provided in the back gate electrode BG and extending in the X-direction. The pair of memory holes MH and the joining section JP are formed in a U shape.

A memory film 15 is provided on side surfaces of the pair of memory holes MH and the joining section JP. Silicon pillars SP are provided further on the center axis side than the memory film 15 in the memory holes MH. A pipe connection PC is provided further on the center axis side than the memory film 15 in the joining section JP. The memory film 15 is formed by stacking a block insulating film, a charge film, and a tunnel insulating film in order from the outer side. Consequently, memory cells are formed in crossing portions of the word lines WL and the silicon pillars SP.

On the end of one silicon pillar SP, a contact plug CP_{SL} embedded in the interlayer insulating film 37 is provided. On the contact plug CP_{SL}, the source line SL embedded in the interlayer insulating film 38 and extending in the Y-direction is provided. On the end of the other silicon pillar SP, a contact plug CP_{BL} embedded in the interlayer insulating film 37 and the interlayer insulating film 38 is provided. On the contact plug CP_{BL} and the interlayer insulating film 38, the bit line BL extending in the X-direction is provided.

The insulating film 11, the barrier metal film 20, and the interlayer insulating films 12, 16, and 36 to 38 are formed of, for example, silicon oxide (SiO) or silicon nitride (SiN). The back gate electrode BG, the electrode film 17, the word lines WL, and the selection gate electrode SG are formed of, for example, silicon (Si) containing boron (B) and metal silicide. The filling film 18 only has to be formed of a material different from the material of the stopper protection films 28. The filling film 18 is formed of, for example, silicon or silicon doped with impurities. The contact plug CP_{SL} the contact plug CP_{BL} the source line SL, and the bit line BL are formed of, for example, tungsten (W).

The stopper protection films 28 are provided between the filling film 18 and the stopper member 14. Therefore, metal such as tantalum in the stopper member 14 is prevented from dispersing to the filling film 18.

A method for manufacturing the integrated circuit device according to the embodiment is described.

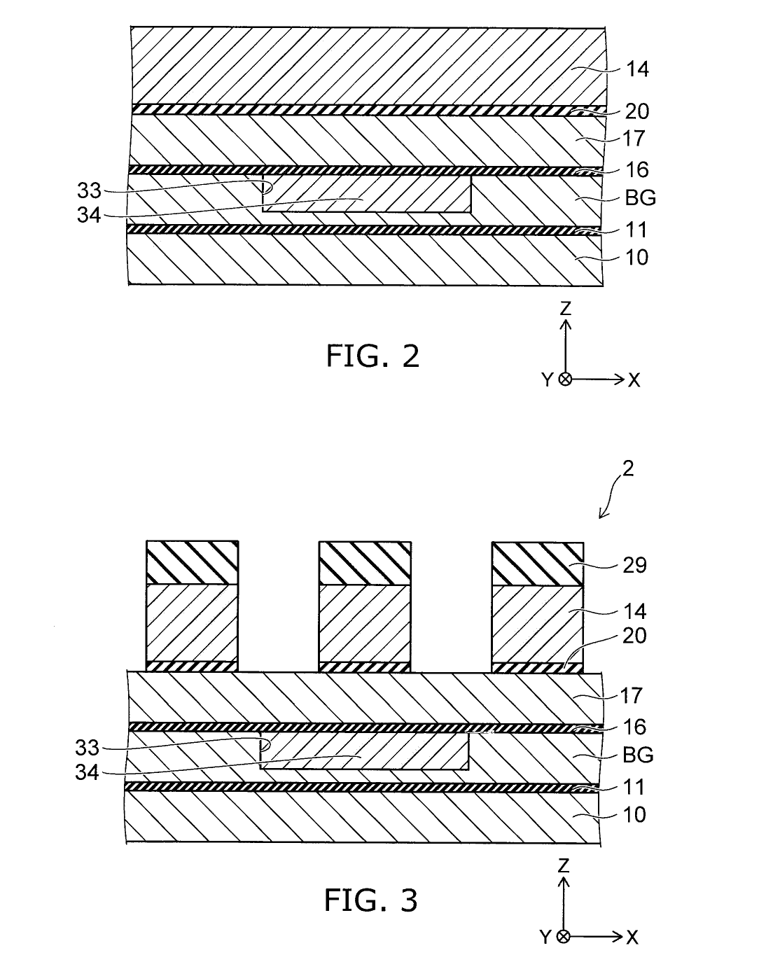

FIGS. 2 to 17 are sectional views illustrating the method for manufacturing the integrated circuit device according to the embodiment.

First, as shown in FIG. 2, the insulating film 11 formed of silicon oxide (SiO) is formed on the silicon substrate 10 by, for example, an HDP-CVD (High Density Plasma Chemical Vapor Deposition) method. The back gate electrode BG is formed on the insulating film 11. Thereafter, a range in which a groove 33 is formed is specified by lithography. The back gate electrode BG is selectively removed by applying etching to form the groove 33. Thereafter, in the groove 33, for example, non-doped silicon is deposited to form a sacrificial film 34. Non-doped means that impurities for imparting electric conductivity are intentionally not added to silicon and impurities are not substantially included other than elements caused by a material gas during film formation. Thereafter, on the back gate electrode BG and the sacrificial film 34, the interlayer insulating film 16, the electrode film 17, the barrier metal film 20, and the stopper member 14 are stacked in this order.

Subsequently, as shown in FIG. 3, ranges in which the stopper member 14 is formed are specified by lithography. Dry etching is applied to the stopper member 14 using hard masks 29 made of silicon oxide containing, for example, DTEOS (Densified Tetra Ethyl Ortho Silicate: Si(OC₂H₅)₄) as a material. Consequently, the stopper member 14 and the barrier metal film 20 are selectively removed to form a structure 2.

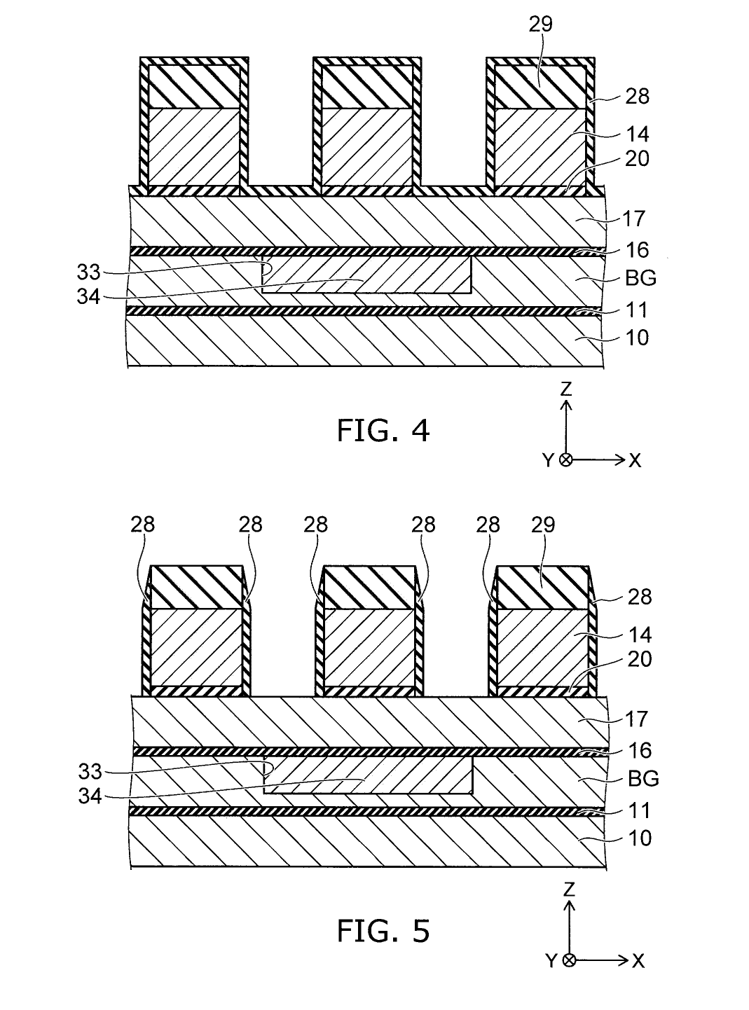

Subsequently, as shown in FIG. 4, on the structure 2, silicon oxide (SiO) having thickness of, for example, approximately 5 nm is deposited using an LP-CVD (Low Pressure Chemical Vapor Deposition) method or an ALD (Atomic Layer Deposition) method to form the stopper films 28. In this case, the stopper protection films 28 are formed on the upper surface of the electrode film 17, the upper surfaces of the hard masks 29, the side surface of the barrier metal film 20, the side surface of the stopper member 14, and the side surfaces of the hard masks 29.

Subsequently, as shown in FIG. 5, the stopper protection films 28 are etched back. Consequently, portions of the stopper protection films 28 deposited on the upper surface of the electrode film 17 and portions of the stopper protection films 28 deposited on the upper surfaces of the hard masks 29 are removed to leave portions deposited on side surfaces of stacked bodies formed by the hard masks 29, the stopper member 14, and the barrier metal film 20. Consequently, the stopper protection films 28 are processed in a sidewall shape.

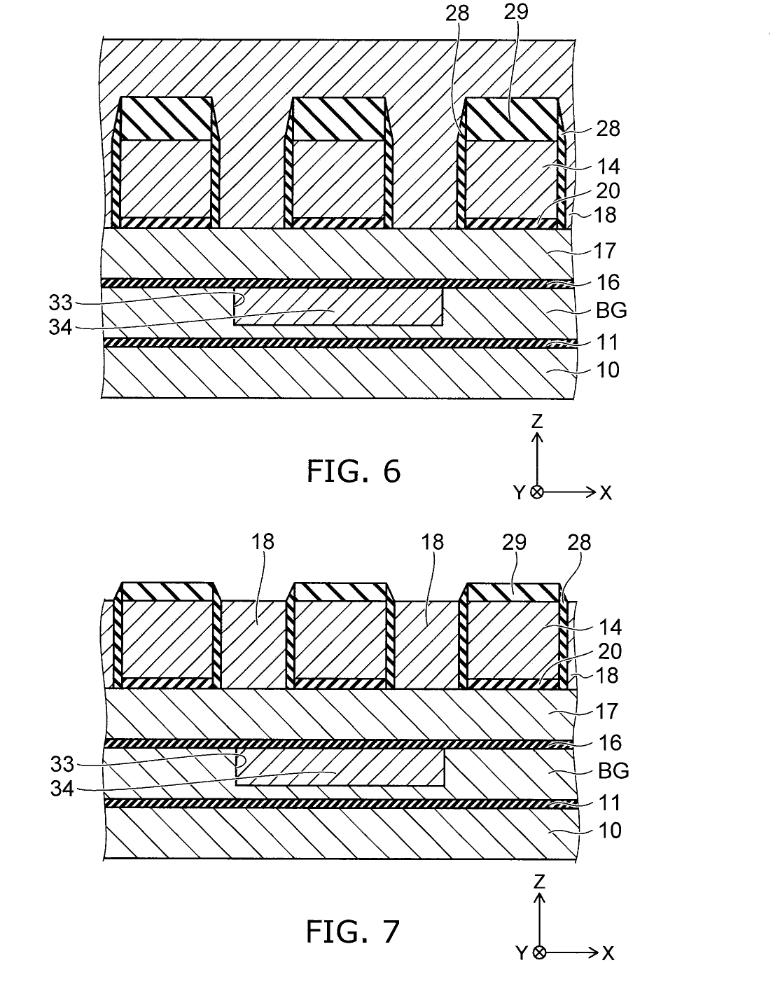

Subsequently, as shown in FIG. 6, the filling film 18 is formed on the electrode film 17, the hard masks 29, and the stopper protection films 28. In this case, since the stopper protection films 28 are present, it is possible to prevent metal such as tantalum in the stopper member 14 from diffusing to the filling film 18.

Subsequently, as shown in FIG. 7, upper parts of the filling film 18 and upper parts of the hard masks 29 are selectively removed by CMP (Chemical Mechanical Polishing) and RIE (Reactive Ion Etching).

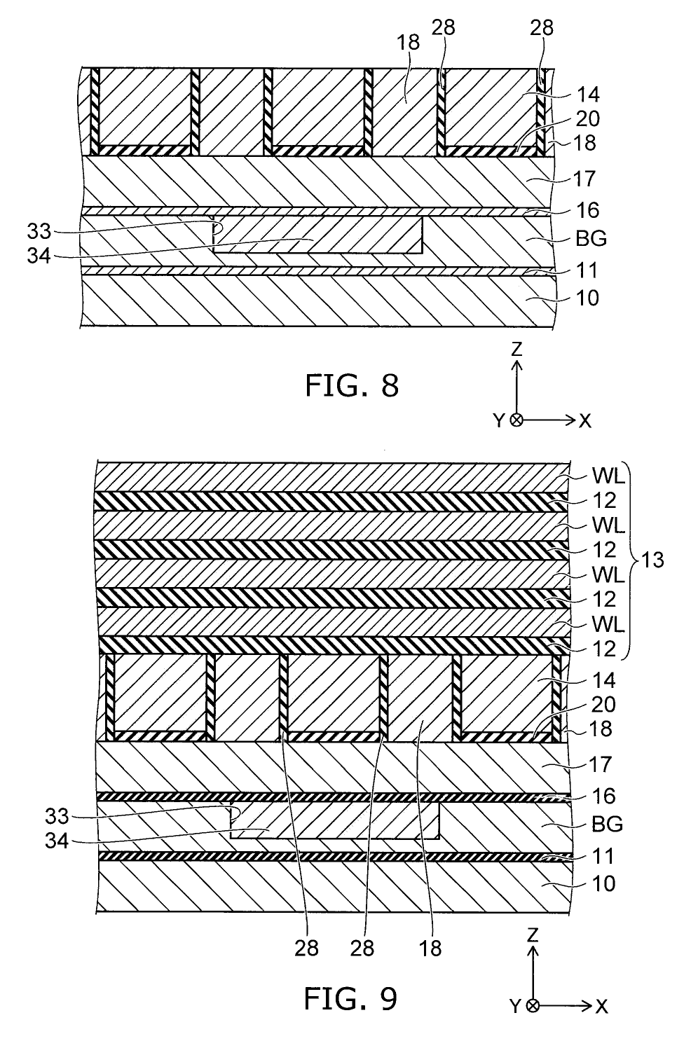

Subsequently, as shown in FIG. 8, planarization treatment is performed to expose the filling film 18, the stopper protection films 28, and the stopper member 14.

Subsequently, as shown in FIG. 9, the interlayer insulating films 12 and the word lines WL are alternately stacked over the entire surfaces of the filling film 18, the stopper protection films 28, and the stopper member 14 to form the stacked body 13.

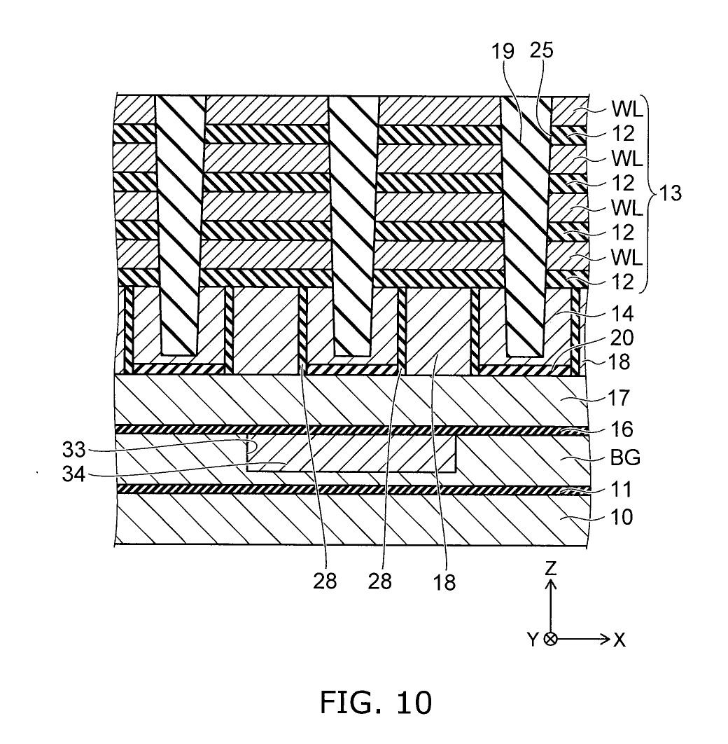

Subsequently, as shown in FIG. 10, for example, ranges in which the lower sections 25 of the slits ST are formed are specified by lithography, the interlayer insulating films 12 and the word lines WL are selectively removed by applying etching to form the lower sections 25 of the slits ST extending in the Y-direction piercing through the stacked body 13 in the Z-direction. Consequently, the word lines WL are separated in the X-direction. Thereafter, an insulating material is filled in the lower sections 25 of the slits ST to form filling films 19.

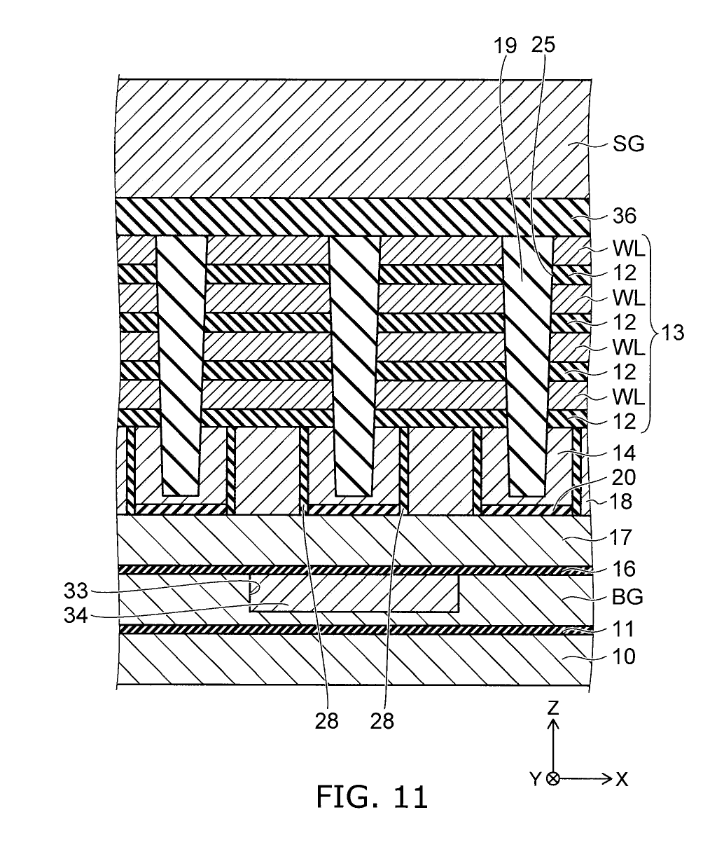

Subsequently, as shown in FIG. 11, on the stacked body 13 and the filling films 19, the interlayer insulating film 36 and the selection gate electrode SG are stacked in this order.

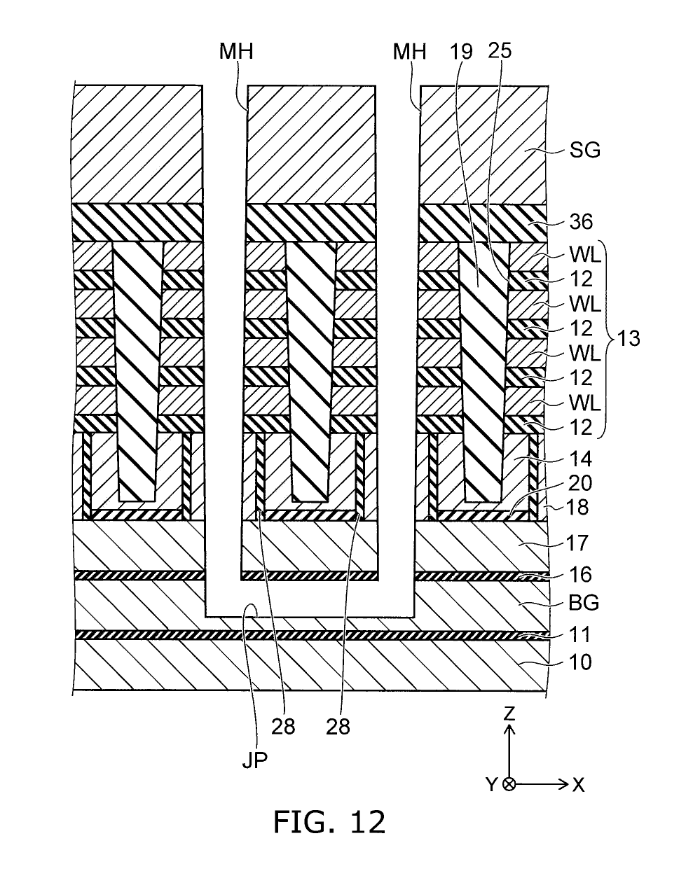

Subsequently, as shown in FIG. 12, ranges in which the memory holes MH are formed are specified by lithography. A stacked body from the selection gate electrode SG to the interlayer insulating film 16 is selectively removed by applying etching to form the memory holes MH piercing through the stacked body in the Z-direction. In this case, the stopper protection films 28 prevent metal such as tantalum in the stopper member 14 from diffusing to the filling film 18. Therefore, it is possible to secure sufficient regions for forming the memory holes MH.

The lower ends of the memory holes MH reach the sacrificial film 34. The sacrificial film 34 is exposed at the lower ends of the memory holes MH. A pair of memory holes MH is formed on one sacrificial film 34 to sandwich the filling film 19. Thereafter, the sacrificial film 34 of non-doped silicon is removed by, for example, wet etching.

According to the removal of the sacrificial film 34, the groove 33 formed in the back gate electrode BG appears. The appeared groove 33 is referred to as the joining section JP. The pair of memory holes MH is joined to one joining section JP. That is, the lower ends of the pair of memory holes MH are joined to one common joining section JP to form one U-shaped hollow.

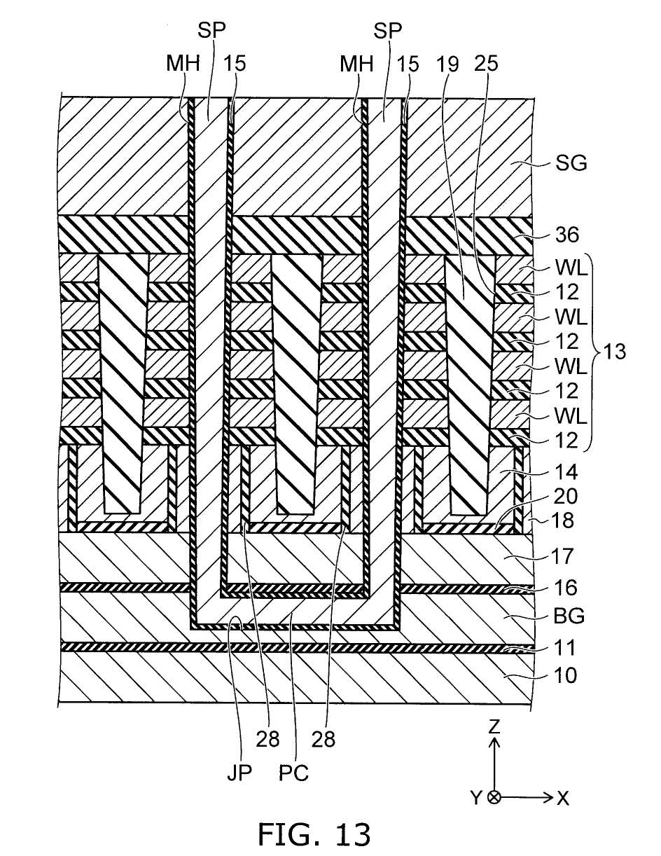

Subsequently, as shown in FIG. 13, a block insulating film, a charge film, and a tunnel insulating film are formed in this order on side surfaces of the pair of memory holes MH and the joining section JP to form the memory film 15. Thereafter, the joining section JP is filled with, for example, silicon to form the pipe connection PC. Thereafter, the pair of memory holes MH is filled with, for example, silicon to form the silicon pillars SP.

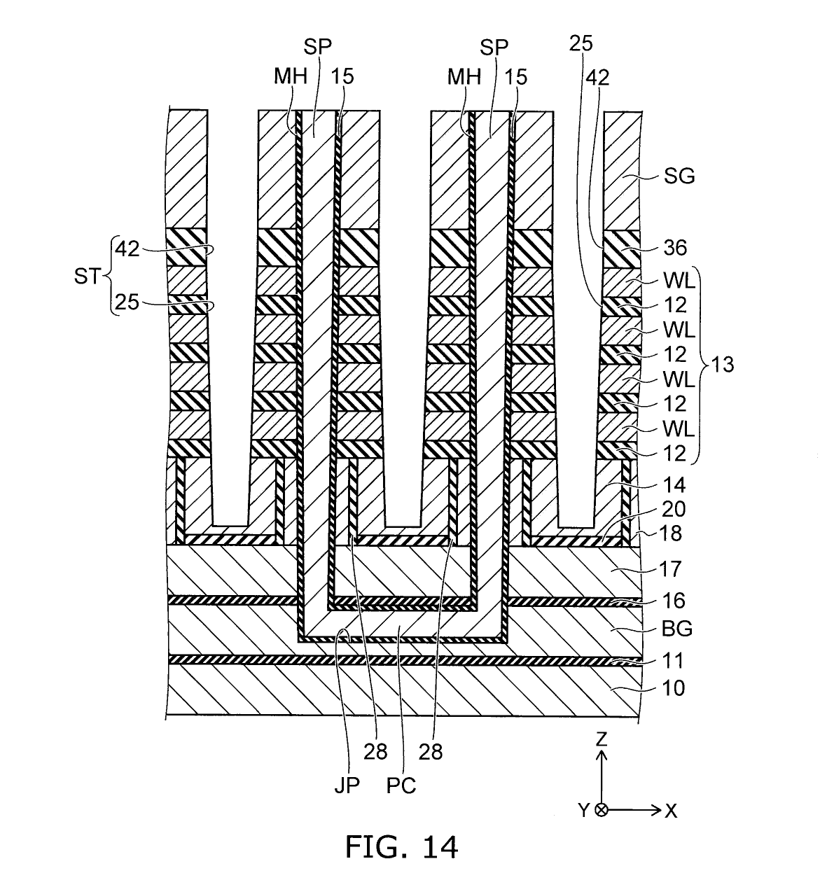

Subsequently, as shown in FIG. 14, ranges in which the upper sections 42 of the slits ST are formed are specified by lithography. A stacked body from the selection gate electrode SG to the interlayer insulating film 36 is selectively removed by applying etching to form the upper sections 42 of the slits ST extending in the Y-direction piercing through the stacked body in the Z-direction. The center surfaces of the upper sections 42 of the slits ST are matched with the center surfaces of the lower sections 25 of the slits ST. Thereafter, the filling films 19 are removed by applying etching to the filling films 19 in the lower sections 25 of the slits ST.

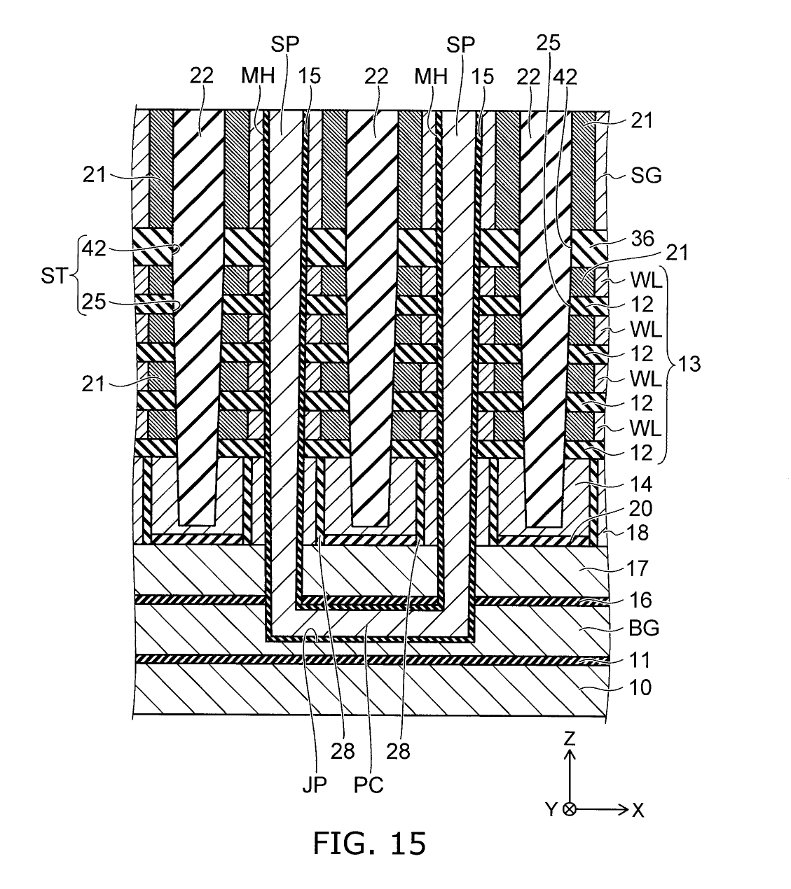

Subsequently, as shown in FIG. 15, metal such as nickel (Ni) or cobalt (Co) is deposited in the slits ST to form metal films. The metal films are caused to react with silicon of the word lines WL to form the silicide 21. Thereafter, unreacted portions in the metal films are removed. Thereafter, an insulating material is filled in the slits ST to form the insulating members 22.

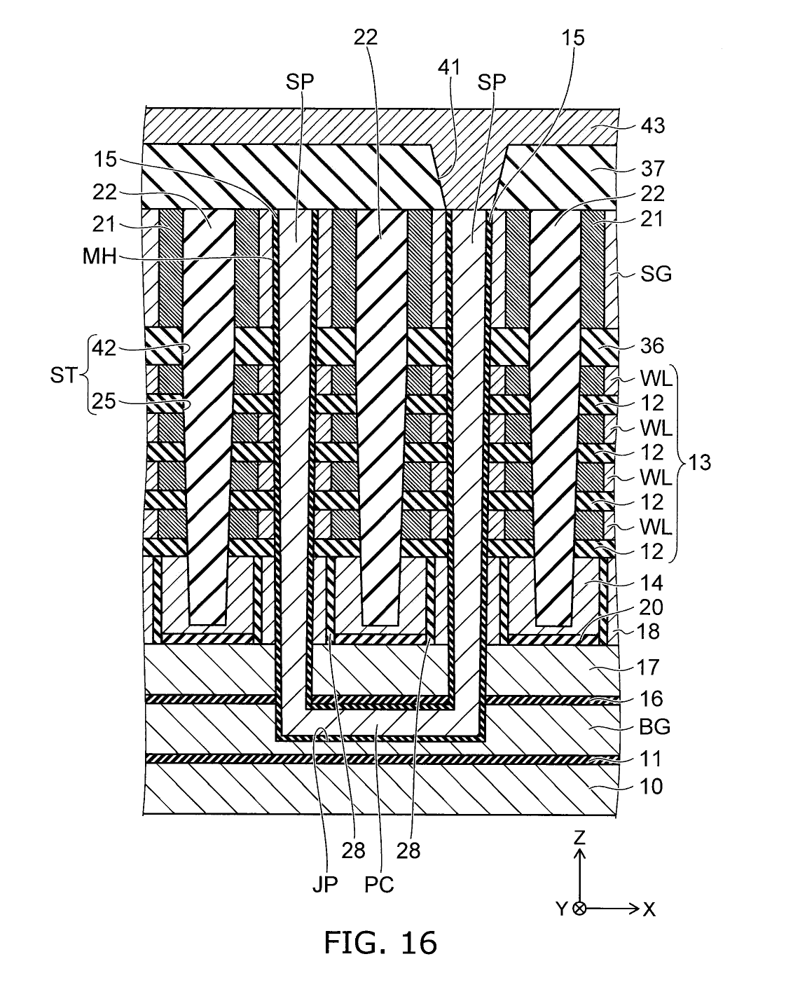

Subsequently, as shown in FIG. 16, after the interlayer insulting film 37 is formed on the selection gate electrode SG, a contact hole 41 is formed by applying lithography and etching. Thereafter, on the interlayer insulating film 37 and the contact hole 41, for example, tungsten (W) is deposited to form a conductive film 43. The conductive film 43 is also filled in the contact hole 41.

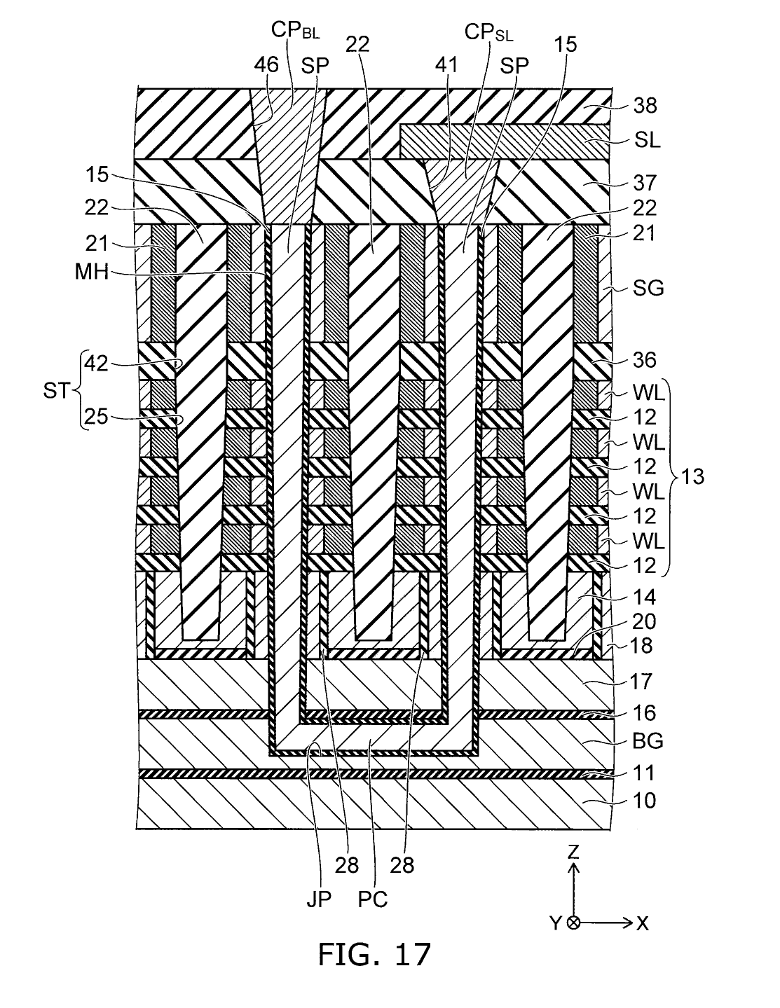

Subsequently, as shown in FIG. 17, the conductive film 43 formed on the upper surface of the interlayer insulating film 37 is removed by, for example, the CMP method to form the contact plug CP_{SL} in the contact hole 41. Thereafter, on the contact plug CP_{SL}, the source line SL extending in the Y-direction is formed by, for example, a damascene method.

Thereafter, after the interlayer insulating film 38 is formed on the interlayer insulating film 37 and the source line SL, a contact hole 46 is formed by applying lithography and etching. Thereafter, the contact plug CP_{BL} is formed by a method same as the method for forming the contact plug CP_{SL}.

Subsequently, as shown in FIG. 1, on the contact plug CP_{BL}, the bit line BL extending in the X-direction is formed by, for example, the damascene method.

Effects of the embodiment are described.

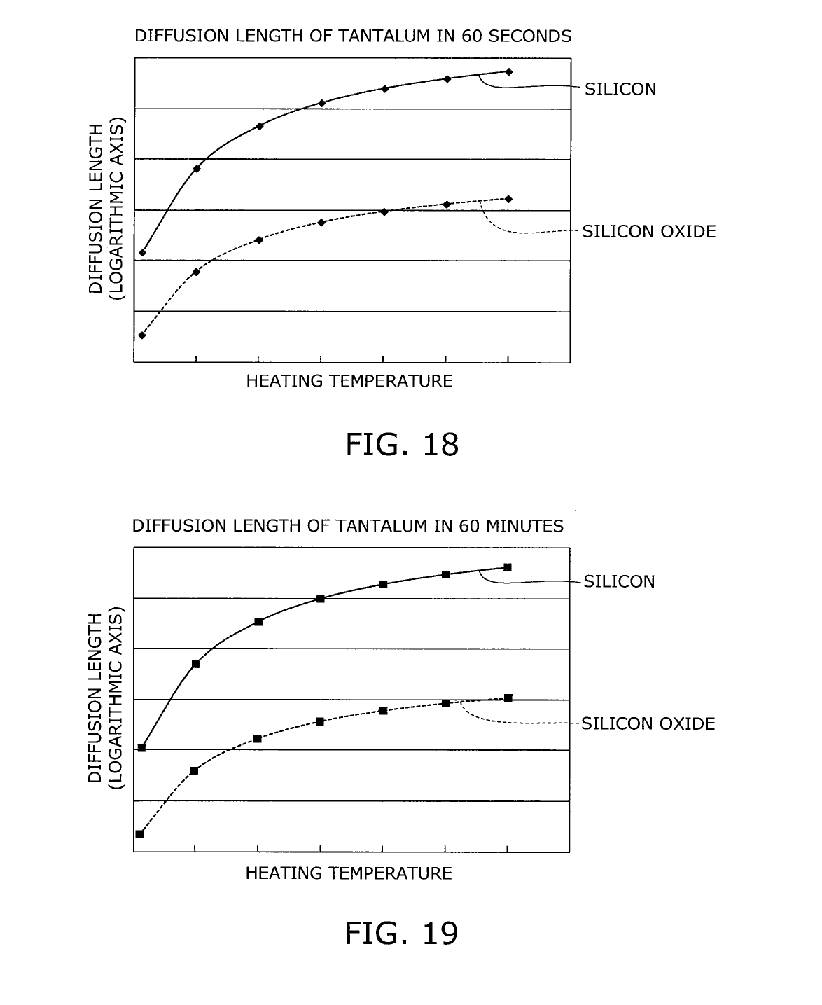

FIG. 18 is a graph illustrating diffusion length of tantalum in 60 seconds with heating temperature plotted on the abscissa and diffusion length plotted on the ordinate.

FIG. 19 is a graph illustrating diffusion length of tantalum in 60 minutes with heating temperature plotted on the abscissa and diffusion length plotted on the ordinate.

As shown in FIGS. 18 and 19, diffusion length of tantalum in silicon oxide is smaller than diffusion length in silicon. Therefore, by providing the stopper members 28 made of silicon oxide having small diffusion length on the side surface of the stopper member 14 made of tantalum, it is possible to prevent diffusion of tantalum in the stopper member 14 to the filling film 18. Consequently, it is possible to secure fixed or more portions necessary for forming the memory holes and prevent deterioration in characteristics of the memory cells.

### Second Embodiment

A second embodiment is described.

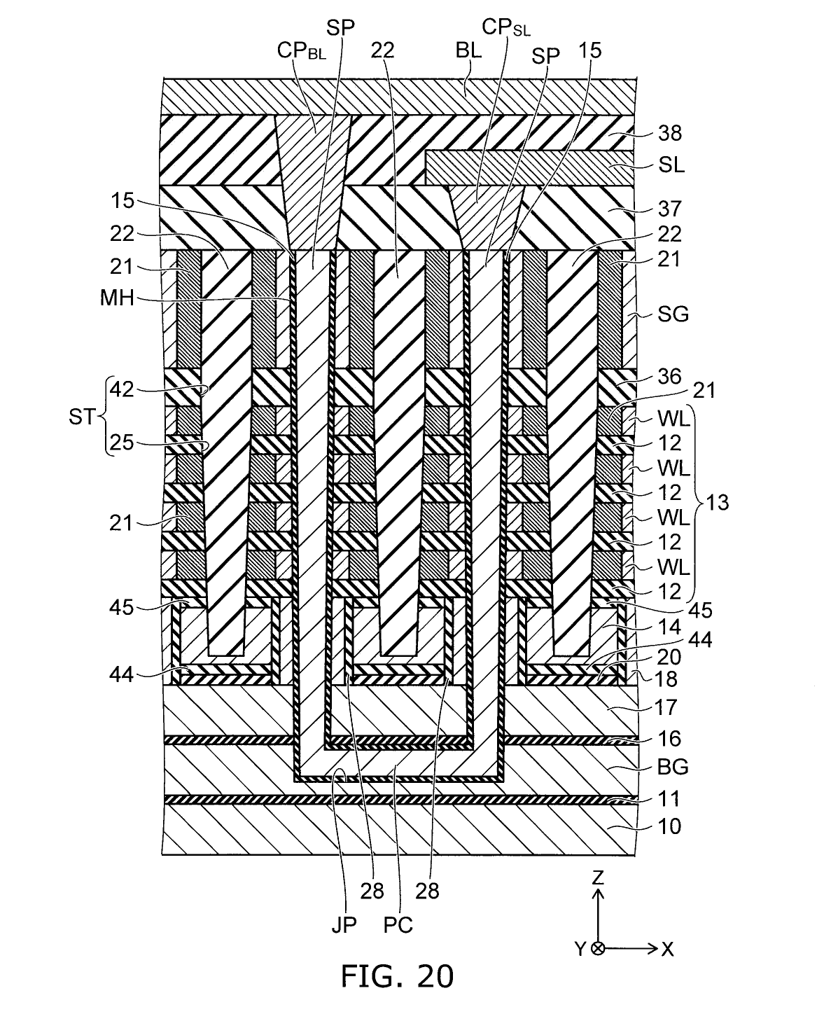

FIG. 20 is a sectional view illustrating an integrated circuit device according to the embodiment.

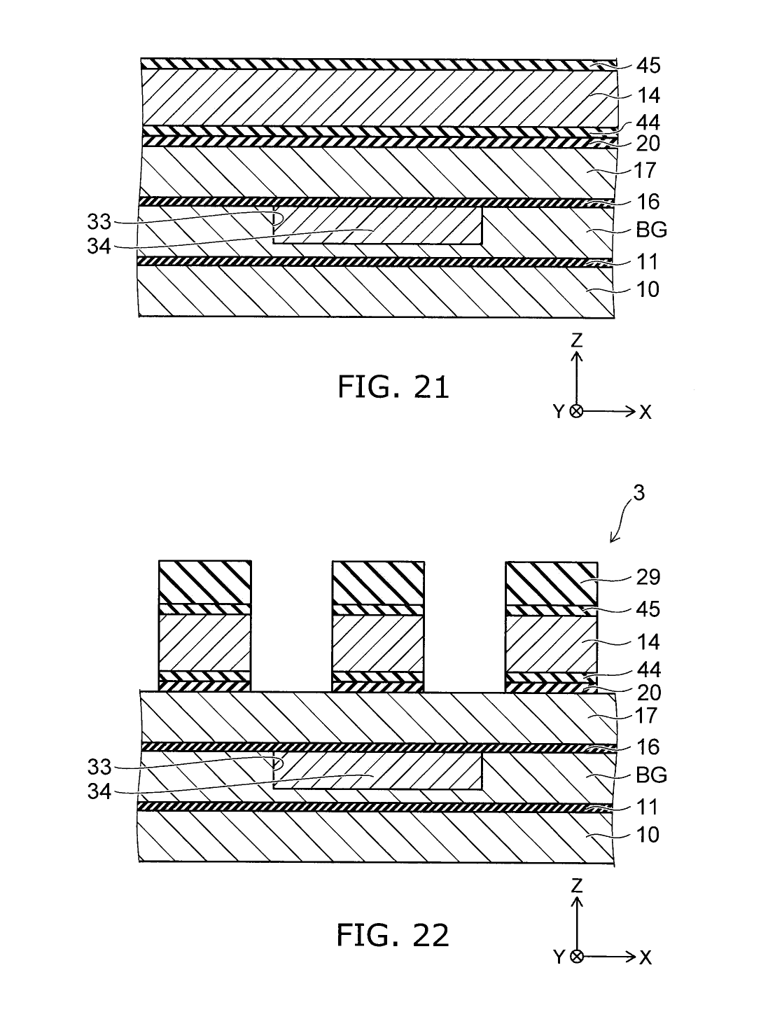

FIGS. 21 to 24 are sectional views showing a method for manufacturing the integrated circuit device according to the embodiment.

First, the configuration of the integrated circuit device according to the embodiment is described.

As shown in FIG. 20, the integrated circuit device according to the embodiment is different from the integrated circuit device (see FIG. 1) according to the first embodiment in that the integrated circuit device includes a stopper protection film 45 on the upper surface of the stopper member 14 and includes a stopper protection film 44 on the lower surface of the stopper member 14.

Components in the embodiment other than those described above are the same as the components in the first embodiment.

The method for manufacturing the integrated circuit device according to the embodiment is described.

The method for manufacturing the integrated circuit device according to the embodiment is different from the first embodiment in that a process for forming the stopper protection films 44 and 45 are added.

First, the method up to the formation of the barrier metal film 20 on the silicon substrate 10 is the same as the method in the first embodiment.

Subsequently, as shown in FIG. 21, the stopper protection film 44, the stopper member 14, and the stopper protection film 45 are stacked on the barrier metal film 20 in this order.

Subsequently, as shown in FIG. 22, ranges in which the stopper member 14 is formed are specified by lithography. Dry etching is applied using the hard masks 29 made of silicon oxide containing DTEOS as a material. Consequently, the stopper protection film 45, the stopper member 14, the stopper protection film 44, and the barrier metal film 20 are selectively removed to form a structure 3.

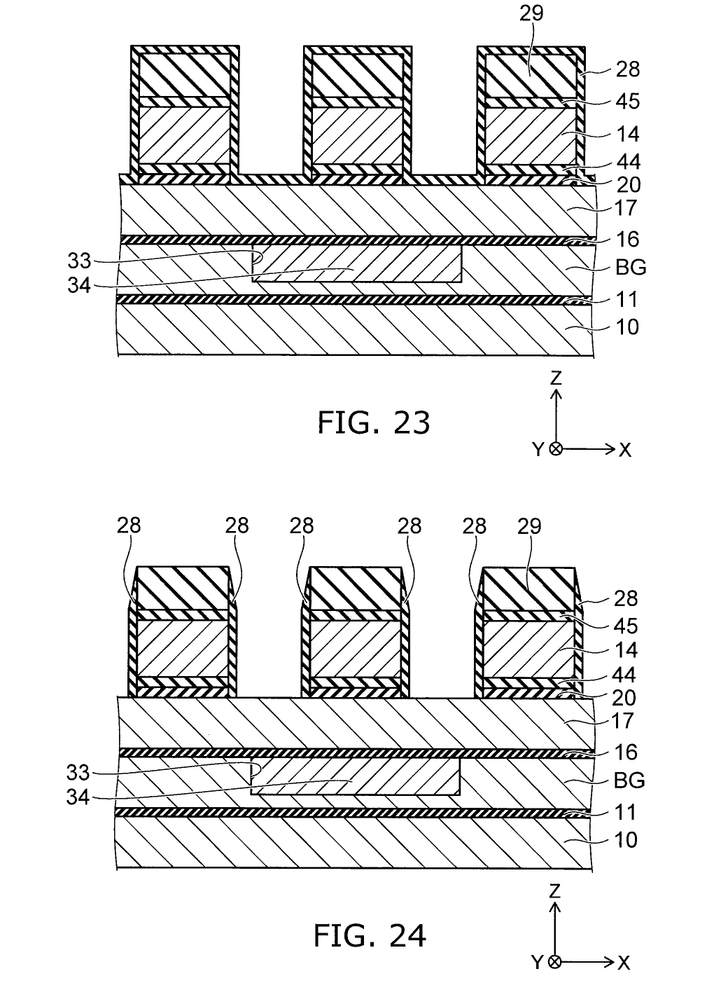

Subsequently, as shown in FIG. 23, on the structure 3, for example, silicon oxide (SiO) having thickness of, for example, approximately 5 nm is deposited to form the stopper protection films 28. In this case, the stopper protection films 28 are formed on the upper surface of the electrode film 17, the upper surfaces of the hard masks 29, the side surface of the barrier metal film 20, the side surface of the stopper protection film 44, the side surface of the stopper member 14, the side surface of the stopper protection film 45, and the side surfaces of the hard masks 29.

Subsequently, as shown in FIG. 24, the stopper protection films 28 are etched back. Consequently, portions of the stopper protection films 28 deposited on the upper surface of the electrode film 17 and portions of the stopper protection films 28 deposited on the upper surfaces of the hard masks 29 are removed to leave portions of the stopper protection films 28 deposited on side surfaces of stacked bodies made of the hard masks 29, the stopper protection film 45, the stopper member 14, the stopper protection film 44, and the barrier metal film 20. Consequently, the stopper protection films 28 are processed in a sidewall shape.

The method from the formation of the filling film 18 to the formation of the bit line BL is the same as the method in the first embodiment.

The manufacturing method in the embodiment other than the above is the same as the manufacturing method in the first embodiment.

Effects of the embodiment are described.

Compared with the integrated circuit device (see FIG. 1) according to the first embodiment, the integrated circuit device according to the embodiment includes the stopper protection film 45 on the upper surface of the stopper member 14 and includes the stopper protection film 44 on the lower surface of the stopper member 14. As a result, it is possible to not only prevent diffusion of metal such as tantalum in the stopper member to the filling film 18 but also prevent diffusion to the interlayer insulating films 12 and the barrier metal film 20.

### Third Embodiment

A third embodiment is described.

The configuration and effects of an integrated circuit device according to the embodiment are the same as the configuration and the effects in the first embodiment. Therefore, a method for manufacturing the integrated circuit device according to the embodiment is described.

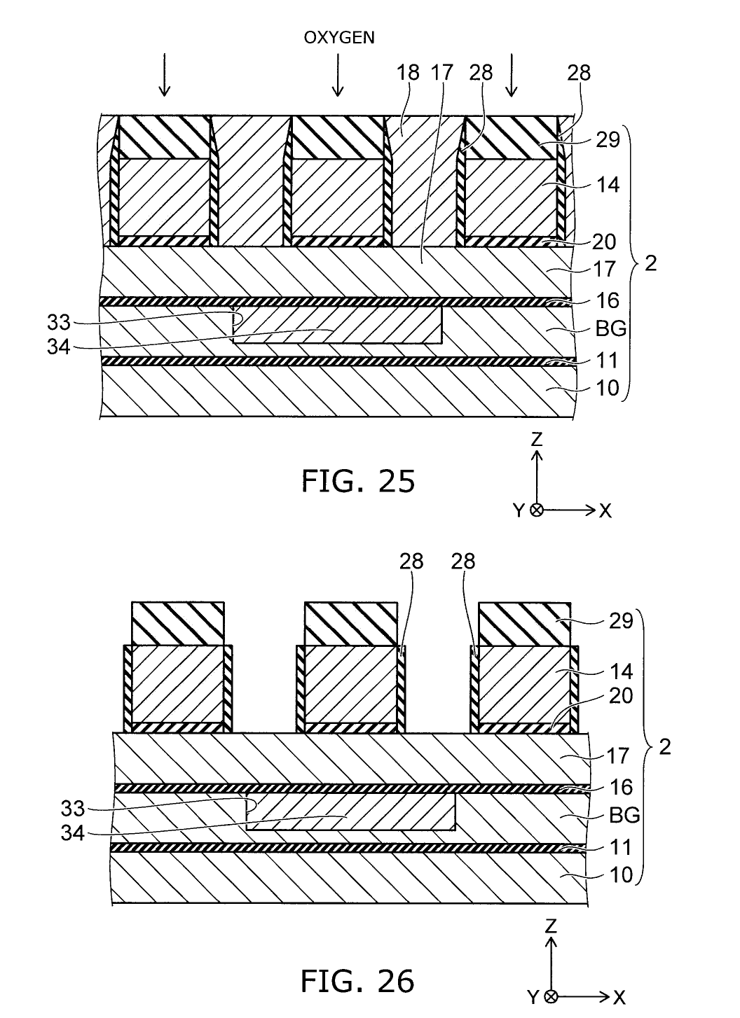

FIG. 25 is a sectional view illustrating the method for manufacturing the integrated circuit device according to the embodiment.

First, the method for manufacturing the integrated circuit device is the same as the method for manufacturing the integrated circuit device according to the first embodiment up to the formation of the structure 2 (FIG. 3).

Subsequently, as shown in FIG. 25, silicon is deposited on the structure 2 to form the filling film 18. In this case, in the beginning of the deposition of the silicon, oxygen is introduced into a deposition chamber (not shown in the figure). Consequently, the oxygen reacts with the deposited silicon and the stopper protection films 28 made of silicon oxide are formed. Thereafter, the introduction of the oxygen is stopped and the silicon is deposited to form the filling film 18 made of the silicon.

The manufacturing method in the embodiment other than the above is the same as the manufacturing method in the first embodiment.

Note that it is also possible that the oxygen is introduced into the deposition chamber in advance and then the silicon is deposited. Consequently, the stopper protection films 28 made of the silicon oxide is formed until the oxygen in the deposition chamber is exhausted. Thereafter, the filling film 18 made of the silicon is formed.

### Fourth Embodiment

A fourth embodiment is described.

FIG. 26 is a sectional view illustrating a method for manufacturing an integrated circuit device according to the embodiment.

First, the method for manufacturing the semiconductor device is the same as the method for manufacturing the integrated circuit device according to the first embodiment up to the formation of the structure 2 (see FIG. 3).

Subsequently, as shown in FIG. 26, the structure 2 is annealed, whereby the side surface of the stopper member 14 is selectively oxidized. The stopper protection films 28 made of tantalum oxide (TaO) is formed on the side surface of the stopper member 14.

Note that, when the annealing is performed, nitrogen may be introduced to form the stopper protection films 28 made of tantalum nitride (TaN) on the side surface of the stopper member 14.

Components, the manufacturing method, and effects in the embodiment other than the above are the same as the components, the manufacturing method, and the effects in the first embodiment.

The interlayer insulating film 16 does not have to be present. The back gate electrode BG, the electrode film 17, and the filling film 18 may be set in contact to be configured to apply the same potential.

According to the embodiments described above, it is possible to prevent diffusion of the material in the stopper member to the periphery. As a result, it is possible to secure fixed or more portions necessary for forming the memory holes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An integrated circuit device comprising:
a substrate;
a stacked body provided on the substrate, insulating films and electrode films being alternately stacked in the stacked body;
a stopper member selectively provided between the substrate and the stacked body;
a first stopper protection film provided on a side surface of the stopper member;
an insulating member provided immediately on the stopper member and configured to pierce through the stacked body in a stacking direction of the insulating films and the electrode films, a lower end of the insulating member disposed in the stopper member; and
a semiconductor pillar provided in a side direction of the insulating member and configured to pierce through the stacked body in the stacking direction.

2. The device according to claim 1, further comprising a second stopper protection film provided on an upper surface of the stopper member.

3. The device according to claim 1, further comprising a second stopper protection film provided on a lower surface of the stopper member.

4. The device according to claim 1, wherein the first stopper protection film is made of silicon oxide or silicon nitride.

5. The device according to claim 2, wherein the second stopper protection film is made of silicon oxide or silicon nitride.

6. The device according to claim 1, further comprising a barrier film provided under the stopper member.

7. The device according to claim 6, wherein the barrier film is made of silicon oxide or silicon nitride.

8. The device according to claim 1, wherein
the semiconductor pillar includes a first semiconductor pillar and a second semiconductor pillar arranged in a second direction perpendicular to the stacking direction, and
the stopper member is disposed between the first semiconductor pillar and the second semiconductor pillar.

9. The device according to claim 8, wherein lower ends of the first semiconductor pillar and the second semiconductor pillar are connected by a semiconductor joining section.

10. The device according to claim 9, further comprising a back gate electrode provided around the semiconductor joining section via an insulating film.

11. The device according to claim 1, wherein the electrode film contains silicon.

12. The device according to claim 1, wherein a material of the electrode films is different from a material of the first stopper protection film.

13. A method for manufacturing an integrated circuit device comprising:
depositing a first material on a first electrode film;
selectively removing the first member to form a stopper member;
forming a first stopper protection film on a side surface of the stopper member;
depositing a third material on the first electrode film other than a portion where the stopper member and the first stopper protection film are formed and forming a filling film;
alternately stacking second insulating films and second electrode films on the stopper member, the first stopper protection film, and the filling film to form a stacked body;
forming, immediately on the stopper member, a slit that pierces through the stacked body in a stacking direction of the second insulating films and the second electrode films and reaches inside the stopper member;
filling the slit with an insulating material to form an insulating member;
forming, in a side direction of the slit, a memory hole that pierces through the stacked body in the stacking direction; and
forming a memory film on a side surface of the memory hole and filling a semiconductor material in the memory hole to form a semiconductor pillar.

14. The method according to claim 13, wherein the forming the first stopper protection film includes:
depositing a second material on a structure made of the first electrode film and the stopper member to form a protection film; and
removing a portion deposited on an upper surface of the first electrode film of the protection film and a portion deposited on an upper surface of the stopper member.

15. The method according to claim 13, wherein the forming the first stopper protection film includes annealing the stopper member.

16. The method according to claim 13, wherein the forming the first stopper protection film includes:
depositing the third material on a structure made of the first electrode film and the stopper member while introducing oxygen; and
depositing the third material after stopping the introduction of the oxygen.

17. The method according to claim 14, further comprising:
depositing the second material on the first electrode film to form a second stopper protection film before the depositing the first material; and
depositing the second material on the stopper member to form a third stopper protection film after the forming the stopper member.

18. The method according to claim 14, wherein the second material is made of silicon oxide or silicon nitride.

19. The method according to claim 14, wherein the third material is different from the second material.

20. The device according to claim 1, wherein
a lower electrode film is disposed between the substrate and the stacked body, and
the first stopper protection film is disposed between the lower electrode film and the stopper member.
